(19) United States
(12) Patent Application Publication
(10) Pub. No.: US 2007/0216456 A1
(43) Pub. Date: Sep. 20, 2007

(54) Delay locked loop and method of locking a clock signal

(76) Inventors: Jeong-Hoon Kook, Seoul (KR); Sung-Man Park, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/651,487

(22) Filed: Jan. 10, 2007

(30) Foreign Application Priority Data
Jan. 10, 2006 (KR) 2006-2568

(51) Int. Cl. H03L 7/06

(52) U.S. Cl. 327/158

(57) ABSTRACT

A delay locked loop includes a variable delay unit, a phase inversion unit, a delay selecting unit, a delay control unit and an inversion control unit. The variable delay unit delays a reference clock signal based on phase difference between a first feedback clock signal and a reference clock signal, outputted from the delay control unit. The phase inversion unit selectively inverts the delayed clock signal in response to a phase inversion control signal and generates a reproduction clock signal. The delay selecting unit selectively delays the first feedback clock signal corresponding to the reproduction clock signal in response to an inversion control termination signal to generate a second feedback clock signal. The inversion control unit generates the phase inversion control signal when the phase difference between the delayed feedback clock signal and the reference clock signal is larger than a half clock-cycle, and generates the inversion control termination signal.

### BACKGROUND OF THE INVENTION

1. Field of the Invention

Example embodiments of the present invention generally relate to electronic circuits such as semiconductor memory devices, and more particularly, embodiments of the present invention relate to a delay locked loop (DLL) and to a method of locking a clock signal.

A claim of priority under 35 USC § 119 is made to Korean Patent Application No. 2006-2568, filed Jan. 10, 2006, in the Korean Intellectual Property Office (KIPO), the contents of which are herein incorporated by reference in their entirety.

2. Description of the Related Art

In synchronous semiconductor memory devices, operations are performed in synchronization with a reference clock signal. In particular, a synchronous semiconductor memory device receives a clock signal provided from a memory controller via a clock input terminal to generate an internal clock signal synchronized through a delay locked loop, and then controls input/output operations of data in synchronization with the generated internal clock signal.

In order to minimize circuit area, a delay locked loop (DLL) in a synchronous semiconductor memory device typically implements an inversion scheme in which a relatively small number of delay cells are utilized. Delay locked loops having an inversion scheme are disclosed, for example, in Korean Patent Laid-Open Publication Nos. 2000-51886 and 2001-83329, and U.S. Patent Application Publication No. 2005-141334.

In an inversion scheme, a delay time may be controlled by inverting a feedback clock signal in the case where a phase difference between a reference clock signal and the feedback clock signal is larger than a half-cycle. In this manner, the feedback clock signal may approach a phase of the reference clock signal within a half-cycle, and thus, the number of delay cells may be reduced to half that of the original number of the delay cells.

A delay locked loop having an inversion scheme is thus considered efficient in the field of semiconductor memory chip design in which space is limited due to substantial areas occupied by cell arrays and logic circuits.

FIGS. 1 and 2 are timing diagrams illustrating an operation of a delay locked loop having a conventional inversion locking scheme. In particular, FIG. 1 is a timing diagram for explaining an operation prior to inversion, and FIG. 2 is a timing diagram for explaining an operation after inversion.

Referring to FIG. 1, a logical level of a clock signal CK is detected within a window interval W. The window interval W is defined between a rising edge “A” of a feedback clock signal FCK and a rising edge of a window feedback clock signal WFCK. An inversion determination is performed according to the logical level of the clock signal CK within the window interval W. In the case where the clock signal CK is logical “high” within the window interval W, a phase inversion is performed. If the clock signal CK is logical “low” within the window interval W, no phase inversion is performed. FIG. 2 illustrates the case where phase inversion has been performed, and the phase of the feedback clock signal FCK is inverted. Thus, the clock signal CK is detected to be a logical “low” within the window interval W which is defined between a rising edge “C” of an inverted feedback clock signal IFCK and a rising edge of an inverted window feedback clock signal WFCK.

Before inversion as shown in FIG. 1, a delay time which is larger than a half-cycle is necessary for synchronizing the rising edge “A” of the feedback clock signal FCK with a rising edge “B” of the clock signal CK. After inversion as shown in FIG. 2, however, a delay time which is less than a half-cycle is necessary for synchronizing a rising edge “C” of an inverted feedback clock signal IFCK with a rising edge “D” of a clock signal CK. For this reason, the inversion scheme requires the provision of fewer delay cells.

However, as explained below with reference to FIGS. 3 and 4, conventional delay locked loops having an inversion scheme may fail to reliably perform inversion locking due to a pulse width change (for example, a change of a duty ratio change) of a clock signal, a clock jitter and the like.

FIGS. 3 and 4 are timing diagrams for explaining an inversion locking failure caused by a change of duty ratio of a clock signal in a delay locked loop having a conventional inversion locking scheme. In particular, FIG. 3 is a timing diagram before inversion, and FIG. 4 is a timing diagram after inversion. Here, the duty ratio of the clock signal is the ratio between the logical “high” pulse with and the logical “low” pulse width.

Referring to FIG. 3, the duty ratio of a clock signal CK is not 50:50, and the clock signal CK is a logical “high” within the window interval W. Thus, inversion is performed and a phase of a feedback clock signal FCK is inverted as shown in FIG. 4. Referring to FIG. 4, in the case where a rising edge “A” of the inverted feedback clock signal IFCK occurs after a rising edge B of the clock signal CK, the rising edge A does not lock the rising edge “A” of the feedback clock signal FCK to the rising edge “B” of the clock signal CK, and instead locks the rising edge “A” to a subsequent rising edge “C” of the clock signal CK. Accordingly, a phase locking time is increased.

In the case of a relatively high frequency, the phase locking time is extended, but the number of delay cells may still be sufficient to lock the rising edge “A” to the rising edge “C” as shown in FIG. 4. However, in the case of a relatively low frequency, the number of the delay cells may not be sufficient, and a locking failure may thus occur.

### SUMMARY OF THE INVENTION

In some example embodiments of the present invention, a delay locked loop is provided which includes a variable delay unit, a phase inversion unit, a delay selecting unit, a delay control unit and an inversion control unit. The variable delay unit is configured to delay a reference clock signal in response to a delay control signal and to generate a corresponding delayed clock signal. The phase inversion unit is configured to selectively invert the delayed clock signal in response to a phase inversion control signal and to generate a corresponding reproduction clock signal. The delay selecting unit is configured to selectively delay a first feedback clock signal which corresponds to the reproduction clock signal in response to an inversion control termination signal, and to generate a corresponding second feedback clock signal. The delay control unit is configured to detect a phase difference between the first feedback clock signal and the reference clock signal in response to the inversion control termination signal, and to generate the delay control signal in accordance with the detected phase difference between the first feedback clock signal and the reference clock signal. The inversion control unit is configured to detect a phase difference between the second feedback clock signal and the reference clock signal, to generate the phase inversion control signal to cause the phase inversion unit to invert the delayed clock signal when the phase difference between the delayed feedback clock signal and the reference clock signal is larger than a half clock-cycle, and then to generate the inversion control termination signal.

In other example embodiments of the present invention, a method of locking a clock signal is provided. The method includes generating a delayed clock signal by delaying a reference clock signal, generating a first feedback clock signal by determining a phase inversion of the delayed clock signal, and generating a second feedback clock signal by delaying the first feedback clock signal for a first delay time before the inversion determination and by transferring the first feedback clock signal without delay after the inversion determination, the first delay time substantially corresponding to a pulse width variation margin of the reference clock signal. The method further includes controlling the phase inversion of the delayed clock signal based on a phase difference between the second feedback clock signal and the reference clock signal, and controlling a delay amount of the delayed clock signal in response to a phase difference between the reference clock signal and the first feedback clock signal after the phase inversion so that the delayed clock signal is synchronized with the reference clock signal.

In still other example embodiments of the present invention, a method of locking a clock signal is provided. The method includes delaying a feedback clock signal to determine a phase inversion of a delayed clock signal, and transferring the feedback clock signal without delay after the inversion determination to control a delay amount of the delayed clock signal in response to a phase difference between a reference clock signal and the feedback clock signal so that the delay clock signal is synchronized with the reference clock signal.

### BRIEF DESCRIPTION OF THE DRAWINGS

FIGS. 1 and 2 are timing diagrams for explaining an operation of a delay locked loop having a conventional inversion locking scheme.

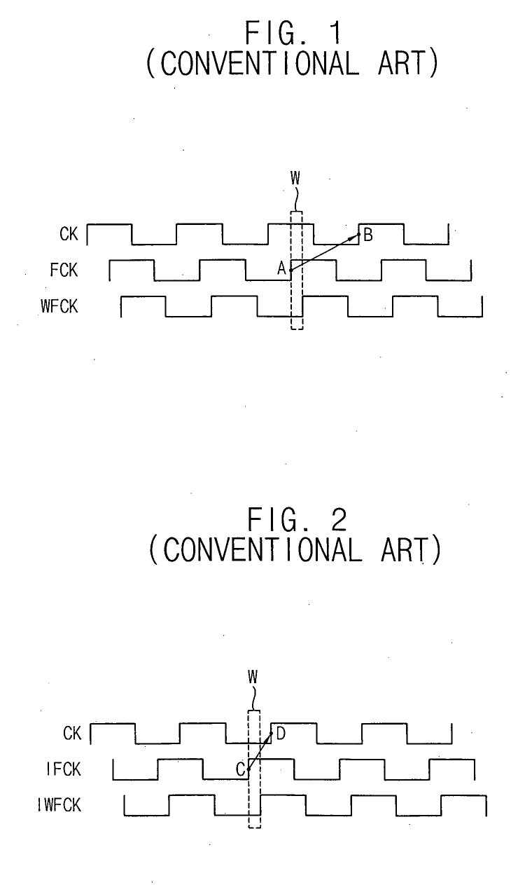

FIGS. 3 and 4 are timing diagrams for explaining an inversion locking failure caused by pulse width variation in a clock signal of a delay locked loop having a conventional inversion locking scheme.

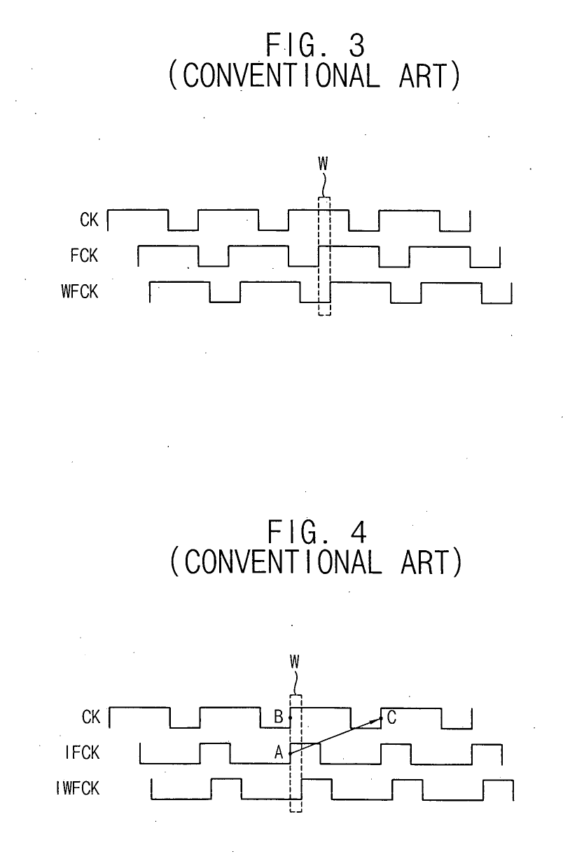

FIG. 5 is a block diagram illustrating a delay locked loop according to an example embodiment of the present invention.

FIG. 6 is a circuit diagram illustrating a delay selecting unit in FIG. 5 according to an example embodiment of the present invention.

FIGS. 7 and 8 are timing diagrams for explaining an operation of a delay locked loop having an inversion locking scheme according to example embodiments of the present invention.

### DESCRIPTION OF THE EMBODIMENTS

Embodiments of the present invention now will be described more fully with reference to the accompanying drawings, in which embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

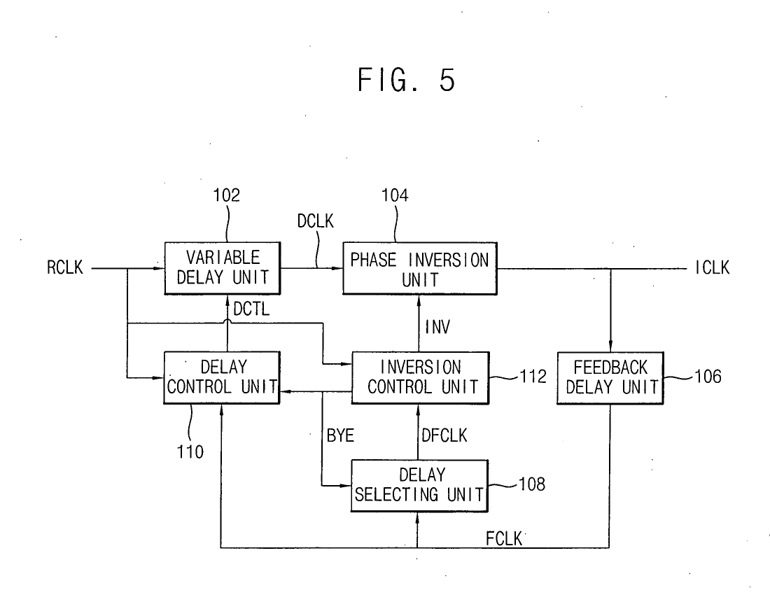

FIG. 5 is a block diagram illustrating a delay locked loop according to example embodiments of the present invention.

Referring to FIG. 5, the delay locked loop may include a variable delay unit 102, a phase inversion unit 104, a delay selecting unit 108, a delay control unit 110, and an inversion control unit 112. The delay locked loop may further include a feedback delay unit 106 as shown in FIG. 5.

The variable delay unit 102 receives a reference clock signal RCLK and delays the reference clock signal RCLK by using a plurality of delay cells so as to generate a delayed clock signal DCLK. The number of the delay cells that are enabled to delay the reference clock signal RCLK may be determined based on a delay control signal DCTL. The variable delay unit 102 need not include a number of delay cells corresponding to one cycle, and may include a total number of delay cells which corresponds to a sum of a half-cycle and a first delay time.

The phase inversion unit 104 receives the delayed clock signal DCLK and inverts the delayed clock signal DCLK or transfers the delayed clock signal DCLK without inversion in response to a phase inversion control signal INV, so as to generate a reproduction clock signal ICLK. The phase inversion unit 104 outputs an inverted signal of the delayed clock signal DCLK when the phase inversion control signal INV is activated, and outputs the delayed clock signal DCLK without inversion when the phase inversion control signal INV is not activated.

The delay locked loop may further include the feedback delay unit 106. The feedback delay unit 106 receives the reproduction clock signal ICLK and delays the same for a transmission delay time, so as to generate a first feedback clock signal FCLK. The transmission delay time corresponds to a delay time for which the reproduction clock signal ICLK is transmitted from an output terminal of the delay locked loop to a point where the reproduction clock signal ICLK is used. A phase of the first feedback clock signal FCLK may be controlled such that the reproduction clock signal ICLK has the same phase as the reference clock signal RCLK at the point where the reproduction clock signal ICLK is used. A delay amount in the feedback delay unit 106 may be set according to delay characteristics of a condition in which a delay locked loop circuit is applied. When the transmission delay time may be negligible, the feedback delay unit 106 may be omitted, and in this case the reproduction clock signal ICLK is the same as the first feedback clock signal FCLK.

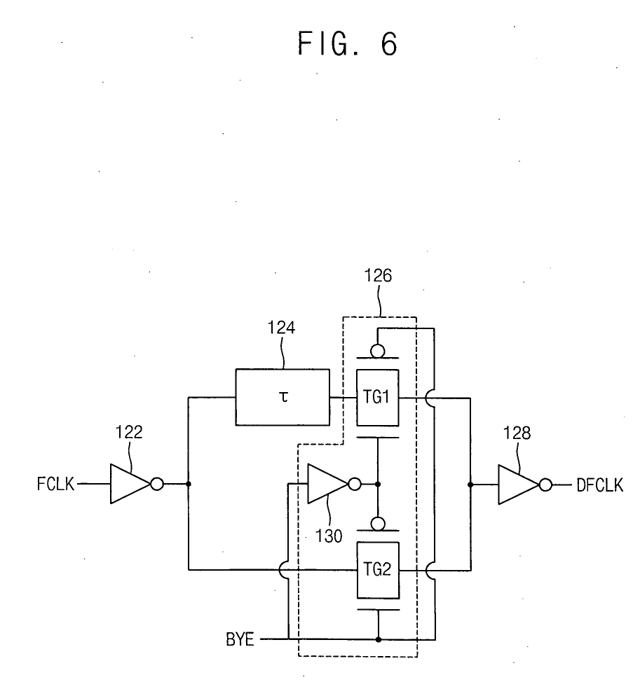

The delay selecting unit 108 receives the first feedback clock signal FCLK and determines whether to delay the first feedback clock signal FCLK for the first delay time in response to an inversion control termination signal BYE so as to generate a second feedback clock signal DFCLK. The first delay time may be determined so as to substantially cover a margin of an unexpected pulse width change of the reference clock signal RCLK. An example of the delay selecting unit 108 will be described in detail later with reference to FIG. 6.

The delay control unit 110 may be enabled in response to the inversion control termination signal BYE to generate the delay control signal DCTL by detecting a phase difference between the reference clock signal RCLK and the first feedback clock signal FCLK. A number of the delay cells that are enabled in the variable delay unit 102 may be determined by the delay control signal DCTL. In other words, the number of the delay cells in the variable delay unit 102 may be determined after inversion determination (that is, after determining whether inversion of the delayed clock signal DCLK is to be executed). By determining the number of the delay cells that are enabled based on the phase difference between the reference clock signal RCLK and the first feedback clock signal FCLK, the delay control unit 110 may control the delay time in the variable delay unit 102. The delay control unit 110 may include a phase detector, a charge pump, a low pass filter and the like, in order to control the variable delay unit 102 by an analog type process.

The inversion control unit 112 may detect a phase difference between the reference clock signal RCLK and the second feedback clock signal DFCLK from the delay selecting unit 108 so as to generate the phase inversion control signal INV and the inversion control termination signal BYE. The inversion control unit 112 may detect a logical state of the reference clock signal RCLK within a window interval to determine whether the delayed clock signal DCLK is to be inverted. The window interval corresponds to a time interval between the second feedback clock signal DFCLK and a window feedback clock signal DWFCLK that is delayed from the feedback clock signal FCLK for the window interval.

Before determining whether inversion is to take place, the inversion control unit 112 may compare a phase of the second feedback clock signal DFCLK with the phase of the reference clock signal RCLK to detect a phase difference between the second feedback clock signal DFCLK and the reference clock signal RCLK. In the case where the phase difference is larger than a half-cycle, the phase inversion control signal INV may be activated to a logical “H” state. In the case where the phase difference is less than a half-cycle, the phase inversion control signal INV may be maintained to a logical “L” state. The inversion control termination signal BYE may be activated in synchronization with a rising edge of the reference clock signal RCLK after comparing the phase difference between the delayed feedback clock signal DFCLK and the reference clock signal RCLK.

FIG. 6 is a circuit diagram illustrating an example of the delay selecting unit shown in FIG. 5.

Referring to FIG. 6, the delay selecting unit 108 may include a first inverter 122, a delay unit 124, a signal selector 126, and a second inverter 128.

The first inverter 122 may be implemented with a CMOS inverter. The first inverter 122 may receive the first feedback clock signal FCLK so as to output an inverted feedback clock signal. An output terminal of the first inverter 122 may be coupled to an input terminal of the delay unit 124 and first input terminal of the signal selector 126.

The delay unit 124 may be coupled between the output terminal of the first inverter 122 and second input terminal of the signal selector 126. The delay unit 124 may control the first delay time. The first delay time may substantially cover a margin of an unexpected pulse width change of the reference clock signal RCLK.

The signal selector 126 may include a third inverter 130 and transmission gates TG1 and TG2. The third inverter 130 may be implemented with a CMOS inverter. An input terminal of the transmission gate TG1 may be coupled to the delay unit 124, and an output terminal of the transmission gate TG1 may be coupled to an input terminal of the second inverter 128. An input terminal of the transmission gate TG2 may be coupled to the output terminal of the first inverter 122, and an output terminal of the transmission gate TG2 may be coupled to the input terminal of the second inverter 128. The inversion control termination signal BYE may be applied to the third inverter 130, and an output of the third inverter 130 (i.e., the inverted signal BYE) may be applied to a non-inverting control terminal of the transmission gate TG1 and an inverting control terminal of the transmission gate TG2. In addition, the inversion control termination signal BYE may be applied to an inverting terminal of the transmission gate TG1 and a non-inverting terminal of the transmission gate TG2.

When the inversion control termination signal BYE corresponds to a logical “low” state, that is, before inversion determination, the transmission gate TG1 may be turned on and the transmission gate TG2 may be turned off. Thus, a signal generated from the delay unit 124 may be selected and provided to the second inverter 128.

When the inversion control termination signal BYE corresponds to a logical “high” state, that is, after inversion determination, the transmission gate TG1 may be turned off and the transmission gate TG2 may be turned on. Thus, a signal generated from the first inverter 122 may be selected and provided to the second inverter 128.

The second inverter 128 may be implemented with a CMOS inverter. The second inverter 128 may receive an output signal of the signal selector 126 so as to invert the output signal of the signal selector 126. An output signal of the second inverter 128 corresponds to the second feedback clock signal DFCLK and is provided to the inversion control unit 112 as shown in FIG. 5.

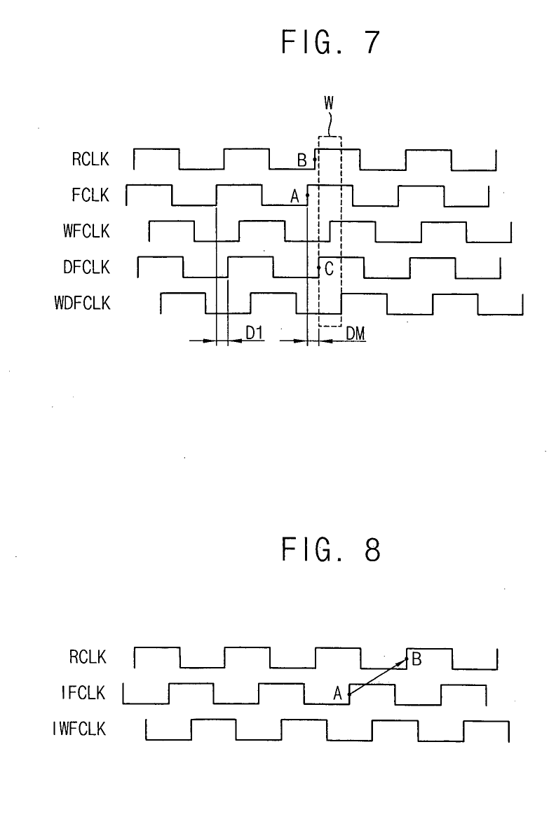

FIGS. 7 and 8 are timing diagrams for explaining an operation of a delay locked loop having an inversion locking scheme according to example embodiments of the present invention. FIG. 7 is a timing diagram before inversion, and FIG. 8 is a timing diagram after inversion.

Referring to FIG. 7, the inversion control termination signal BYE that is provided to the delay selecting unit 108 may be maintained at a logical “low” state before inversion determination so that the second feedback clock signal DFCLK that is delayed from the feedback clock signal FCLK for the first delay time D1 may be applied to the inversion control unit 112. The inversion control unit 112 may compare the phase of the reference clock signal RCLK with the phase of the second feedback clock signal DFCLK. A logical level of the reference clock signal RCLK may be detected within a window interval W that is determined by the second feedback clock signal DFCLK and the window feedback clock signal WDFCLK.

As shown in FIG. 7, a rising edge “C” of the second feedback clock signal DFCLK may be located later with respect to a rising edge “A” of the feedback clock signal FCLK for a pulse width change margin DM of the reference clock signal RCLK. Thus, although a rising edge “B” of the reference clock signal RCLK is located later with respect to the rising edge “A” of the feedback clock signal FCLK, the rising edge “C” of the second feedback clock signal DFCLK is located later with respect to the rising edge “B” of the reference clock signal RCLK. As such, the inversion determination may be appropriately performed.

According to the inversion determination, the delayed clock signal DCLK may be generated as the reproduction clock signal ICLK in the phase inversion unit 104 by inverting the phase of the delayed clock signal DCLK, and the first feedback clock signal FCLK may be generated in the feedback delay unit 106 based on the reproduction clock signal ICLK. The first feedback clock signal FCLK may be applied to the delay selecting unit 108.

When the inversion determination is terminated, the inversion control termination signal BYE may be activated by transitioning from a logical “low” state to a logical “high” state. Thus, the second feedback clock signal DFCLK may be generated by transferring the first feedback clock signal FCLK without delay through the delay selecting unit 108.

Referring to FIG. 8, after the inversion determination, the delay control unit 110 may generate the delay control signal DCTL to control the variable delay unit 102 so that a rising edge “A” of an inverted feedback clock signal IFCLK follows a rising edge “B” of the reference clock signal RCLK. A number of the delay cells that are enabled in the variable delay unit 102 may be determined based on the delay control signal DCTL.

As described above, the delay locked loop having an inversion locking scheme according to example embodiments of the present invention may prevent or reduce the probability of a locking failure caused by a pulse width change of a clock signal such as a duty ratio change, a clock jitter, an unexpected pulse width change, and the like.

In addition, according to the delay locked loop having an inversion locking scheme according to example embodiments of the present invention, inversion determination may be performed effectively with a small number of the delay cells so that an operating frequency may be expanded to a low frequency and a size of the delay locked loop circuitry may be reduced.

Having thus described example embodiments of the present invention, it is to be understood that the invention defined by the appended claims is not to be limited by particular details set forth in the above description as many apparent variations thereof are possible without departing from the spirit or scope thereof as hereinafter claimed.

What is claimed is:

1. A delay locked loop comprising:
a variable delay unit configured to delay a reference clock signal in response to a delay control signal and to generate a corresponding delayed clock signal;
a phase inversion unit configured to selectively invert the delayed clock signal in response to a phase inversion control signal and to generate a corresponding reproduction clock signal;
a delay selecting unit configured to selectively delay a first feedback clock signal which corresponds to the reproduction clock signal in response to an inversion control termination signal, and to generate a corresponding second feedback clock signal;
a delay control unit configured to detect a phase difference between the first feedback clock signal and the reference clock signal in response to the inversion control termination signal, and to generate the delay control signal in accordance with the detected phase difference between the first feedback clock signal and the reference clock signal; and
an inversion control unit configured to detect a phase difference between the second feedback clock signal and the reference clock signal, to generate the phase inversion control signal to cause the phase inversion unit to invert the delayed clock signal when the phase difference between the delayed feedback clock signal and the reference clock signal is larger than a half clock-cycle, and then to generate the inversion control termination signal.

2. The delay locked loop of claim 1, further comprising a feedback delay unit configured to delay the reproduction clock signal and to generate the corresponding first feedback clock signal.

3. The delay locked loop of claim 2, wherein the delay selecting unit comprises:
a first inverter configured to invert the first feedback clock signal;
a delay unit configured to delay an output signal of the first inverter for a first delay time;
a signal selector configured to select one of an output signal of the delay unit and the output signal of the first inverter in response to the inversion control termination signal; and
a second inverter configured to invert an output signal of the signal selector, wherein an output signal of the second inverter corresponds to the second feedback clock signal.

4. The delay locked loop of claim 3, wherein the first delay time substantially corresponds to a pulse width variation margin of the reference clock signal.

5. The delay locked loop of claim 4, wherein the variable delay unit comprises delay cells, wherein a number of the delay cells corresponding to a sum of the half clock-cycle and the first delay time.

6. A method of locking a clock signal, comprising:
generating a delayed clock signal by delaying a reference clock signal;
generating a first feedback clock signal by determining a phase inversion of the delayed clock signal;
generating a second feedback clock signal by delaying the first feedback clock signal for a first delay time before the inversion determination and by transferring the first feedback clock signal without delay after the inversion determination, the first delay time substantially corresponding to a pulse width variation margin of the reference clock signal;
controlling the phase inversion of the delayed clock signal based on a phase difference between the second feedback clock signal and the reference clock signal; and
controlling a delay amount of the delayed clock signal in response to a phase difference between the reference clock signal and the first feedback clock signal after the phase inversion so that the delayed clock signal is synchronized with the reference clock signal.

7. A method of locking a clock signal, comprising:
delaying a feedback clock signal to determine a phase inversion of a delayed clock signal; and
transferring the feedback clock signal without delay after the inversion determination to control a delay amount of the delayed clock signal in response to a phase difference between a reference clock signal and the feedback clock signal so that the delay clock signal is synchronized with the reference clock signal.
